(19) United States
(12) Patent Application Publication
(10) Pub. No.: US 2020/0176255 A1
(43) Pub. Date: Jun. 4, 2020

(54) METHODS OF FORMING SUBLITHOGRAPHIC FEATURES OF A SEMICONDUCTOR DEVICE

(71) Applicant: Micron Technology, Inc., Boise, ID (US)

(72) Inventors: Akash Nigam, Bengaluru (IN); Rajesh N. Gupta, Bangalore (IN)

(21) Appl. No.: 16/208,122

(22) Filed: Dec. 3, 2018

(51) Int. Cl. H01L 21/033; H01L 21/768

(52) U.S. Cl. CPC H01L 21/0338; H01L 21/0335; H01L 21/76877; H01L 21/76816; H01L 21/0337

(57) ABSTRACT

A method of forming sublithographic features. The method comprises forming a pattern of lines at a first pitch, the lines comprising horizontal portions and sloped portions. A spacer material is formed adjacent to the lines and portions of the spacer material are removed to form spacers on the lines, the spacers comprising a second pitch. The lines are removed. A sloped profile of the lines prevents the formation of loops of the spacer material, enabling the formation of sublithographic features without using a chop mask or chop mask process acts. Additional methods are disclosed.

### TECHNICAL FIELD

Embodiments disclosed herein relate to semiconductor device fabrication. More particularly, embodiments of the disclosure relate to methods of forming sublithographic features of semiconductor devices.

### BACKGROUND

Semiconductor device designers often desire to increase the level of integration or density of features within a semiconductor device by reducing the dimensions of the individual features and by reducing the distance between neighboring features. Semiconductor device designers also desire to design architectures that are not only compact, but offer simplified designs. A continuing goal of the semiconductor industry has been to increase the density of the features on the semiconductor devices. Photolithography techniques are typically used to form the features at a desired pitch, with the pitch dependent on the photolithography technique that is used. However, further reductions in feature size are limited by the minimum pitch achievable by the photolithography technique. As shown in FIGS. 1A-3, a pitch multiplication (e.g., pitch doubling, pitch quadrupling) process is used to form sublithographic features at a pitch less than the minimum pitch of the photolithography technique. The pitch multiplication is used to extend the capabilities of the photolithography technique beyond its minimum pitch to form sublithographic features having a pitch of less than about 100 nm.

During pitch multiplication, a photoresist material is formed on a base material and patterned to form patterned photoresist material 2 at a desired pitch P1, as shown in FIG. 1A. Portions of the patterned photoresist material 2 are removed, forming photoresist features 4 having smaller dimensions than the patterned photoresist material 2, as shown in FIG. 1B. A spacer material 6 is conformally formed over the photoresist features 4, as shown in FIG. 1C. Portions of the spacer material 155 are removed, forming spacers 8 on vertical sidewalls of the photoresist features 4, as shown in FIG. 1D. The photoresist features 4 are also referred to in the art as so-called “dummy lines.” At this stage of the pitch multiplication process, the spacers 8 are configured as so-called “loops” 10, which surround the photoresist features 4, as shown in FIGS. 2 and 3. After removing a portion of the spacer material 6 to open the loops 10, the photoresist features 4 are removed, forming a pattern of the spacers 8 having a smaller pitch than the pitch of the photoresist features 4, as shown in FIG. 1E. The spacers 8 are separated from one another by a distance equal to the width of the photoresist features 4. The pitch multiplication process is, therefore, used to form multiple spacers 8 for each photoresist feature 4 that was initially formed.

As shown in FIG. 2, the loops 10 surround the photoresist features 4 and if portions thereof are not removed (e.g., opened), the features formed by the pitch multiplication process will short. To prevent shorting, a portion of the spacer material 6 is removed (indicated by dashed lines in FIG. 2) to isolate adjacent spacers 8 formed from the spacer material 6 from one another. A chop mask 12 is used to remove the ends of the loops 10, as shown in FIG. 3, to prevent shorting of the features formed by the pitch multiplication process. The chop mask 12 is formed of a protective material and is formed over the ends of the loops 10. The chop mask 12 is used to remove the ends of the loops 10, forming the spacers 8 separated from one another by the photoresist features 4. The chop mask 12 is then removed. For every pitch multiplication act that is conducted, one chop mask 12 is needed to remove (e.g., open) the ends of the loops 10. Since the opening of the loops 10 requires formation, patterning, and removal of the chop mask 12, the opening of the loops 10 increases the complexity and amount of time of the pitch multiplication process. In some semiconductor fabrication processes, multiple chop masks 12 and chop mask removal acts are conducted to form the sublithographic features at a desired density. Therefore, conventional pitch multiplication processes require one or more chop masks 12 to open the loops 10. The chop mask 12 is used in conjunction with the pitch multiplication process to form the pattern of spacers 8. The spacers 8 correspond to the sublithographic features ultimately to be formed or to openings between the sublithographic features depending on the subsequent processing acts that are conducted.

### BRIEF DESCRIPTION OF THE DRAWINGS

FIGS. 1A-1E are cross-sectional views showing various stages of a conventional pitch multiplication process;

FIG. 2 is a top down view of FIG. 1D;

FIG. 3 is a perspective view of a chop mask act of a conventional pitch multiplication process;

FIGS. 4, 7, 9, and 12 are perspective views showing various stages of forming sublithographic features in accordance with embodiments of the disclosure;

FIGS. 5 and 11 are top down views showing various stages of forming sublithographic features in accordance with embodiments of the disclosure;

FIGS. 6A and 6B are cross-sectional views showing additional sloped profiles of lines formed in accordance with embodiments of the disclosure;

FIGS. 8 and 10 are cross-sectional views showing various stages of forming sublithographic features in accordance with embodiments of the disclosure;

FIG. 13 is a schematic block diagram illustrating a semiconductor device including the sublithographic features formed in accordance with embodiments of the disclosure; and

FIG. 14 is a schematic block diagram illustrating a system including the sublithographic features formed in accordance with embodiments of the disclosure.

### DETAILED DESCRIPTION

Methods of forming sublithographic features are disclosed. The methods according to embodiments of the disclosure are used to form semiconductor devices, such as memory devices, having the sublithographic features. The sublithographic features are formed by modified pitch multiplication processes or spacer formation processes that utilize lines (e.g., dummy lines) having a sloped profile. The methods reduce or eliminate the use of so-called “chop masks” and chop mask process acts by using a pattern of lines having a sloped profile. The methods reduce or eliminate the number of chop masks used or chop mask process acts conducted during the pitch multiplication process. A spacer material formed adjacent to the lines also exhibits the sloped profile. When portions of the spacer material are removed to form spacers adjacent to the lines, no loops of the spacer material are formed surrounding the lines. The sloped profile of the lines prevents the formation of the loops of the spacer material. Therefore, the semiconductor devices are formed without using chop masks or chop mask process acts during the pitch multiplication process. By reducing or eliminating the number of chop masks used or chop mask process acts conducted, fabrication costs of the semiconductor device are significantly reduced. The methods also improve efficiency and simplify the pitch multiplication process by reducing the number of acts conducted. Therefore, the semiconductor devices may be fabricated by simplified processes.

The sublithographic features have a critical dimension (CD) of less than about 100 nm or less than about 50 nm, such as from about 10 nm to about 95 nm, from about 20 nm to about 90 nm, from about 20 nm to about 80 nm, from about 20 nm to about 70 nm, from about 20 nm to about 60 nm, from about 20 nm to about 50 nm, from about 20 nm to about 40 nm, from about 20 nm to about 30 nm, from about 40 nm to about 80 nm, from about 40 nm to about 70 nm, from about 40 nm to about 60 nm, from about 40 nm to about 50 nm, from about 60 nm to about 90 nm, from about 60 nm to about 80 nm, from about 60 nm to about 70 nm, from about 80 nm to about 95 nm, or from about 80 nm to about 90 nm. The embodiments of the disclosure may be used to form any sublithographic features that utilize a spacer formation process, such as a pitch multiplication process. In some embodiments, patterns of conductive features having the sublithographic CDs are formed.

The following description provides specific details, such as material types, material thicknesses, and process conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete description of a semiconductor device or a complete process flow for manufacturing the semiconductor device and the structures described below do not form a complete semiconductor device. Only those process acts and structures necessary to understand the embodiments described herein are described in detail below. Additional acts to form a complete semiconductor device may be performed by conventional techniques.

The materials described herein may be formed by conventional techniques including, but not limited to, spin coating, blanket coating, chemical vapor deposition (CVD), atomic layer deposition (ALD), plasma enhanced ALD, or physical vapor deposition (PVD). Alternatively, the materials may be grown in situ. Depending on the specific material to be formed, the technique for depositing or growing the material may be selected by a person of ordinary skill in the art. The removal of materials may be accomplished by any suitable technique including, but not limited to, etching, abrasive planarization (e.g., chemical-mechanical planarization), or other known methods unless the context indicates otherwise.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms “a,” “an,” and “the” are intended to include the plural forms as well, unless the context clearly indicates otherwise.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the term “chop mask” refers to a photolithography mask used in conjunction with pitch multiplication acts to form sublithographic features. The chop mask is a noncritical mask having a lower photolithography resolution than the CD of the sublithographic features.

As used herein, the term “configured” refers to a size, shape, material composition, and arrangement of one or more of at least one structure and at least one apparatus facilitating operation of one or more of the structure and the apparatus in a pre-determined way.

As used herein, the term “pitch” refers to a distance between identical points in two adjacent (i.e., neighboring) features of a repeating pattern.

As used herein, the term “pitch multiplication” refers to reducing the pitch of a pattern of features by a certain factor. Pitch multiplication includes pitch doubling, pitch quadrupling, pitch octupling, etc. As is conventional, reducing the pitch of the pattern of features by one-half is referred to as pitch doubling, reducing the pitch by one-quarter is referred to as pitch quadrupling, etc. The pitch reduction may be relative to an initial pitch of a pattern of lines or a minimum pitch of a photolithography technique used to form the pattern of lines.

As used herein, the term “selectively etchable” means and includes a material that exhibits a greater etch rate responsive to exposure to a given etch chemistry and/or process conditions relative to another material exposed to the same etch chemistry and/or process conditions. For example, the material may exhibit an etch rate that is at least about five times greater than the etch rate of another material, such as an etch rate of about ten times greater, about twenty times greater, or about forty times greater than the etch rate of the another material. Etch chemistries and etch conditions for selectively etching a desired material may be selected by a person of ordinary skill in the art.

As used herein, the term “semiconductor device” includes without limitation a memory device, as well as other semiconductor devices which may or may not incorporate memory, such as a logic device, a processor device, or a radiofrequency (RF) device. Further, a semiconductor device may incorporate memory in addition to other functions such as, for example, a so-called “system on a chip” (SoC) including a processor and memory, or a semiconductor device including logic and memory.

As used herein, the term “sloped” refers to an oblique (e.g., slanted) surface that departs from a horizontal direction.

As used herein, the term “substantially” in reference to a given parameter, property, or condition means and includes to a degree that one of ordinary skill in the art would understand that the given parameter, property, or condition is met with a degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “substrate” means and includes a base material or construction upon which additional materials are formed. The substrate may be a semiconductor substrate, a base semiconductor layer on a supporting structure, a metal electrode, or a semiconductor substrate having one or more materials, layers, structures, or regions formed thereon. The materials on the semiconductor substrate may include, but are not limited to, semiconductive materials, insulating materials, conductive materials, etc. The substrate may be a conventional silicon substrate or other bulk substrate comprising a layer of semiconductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

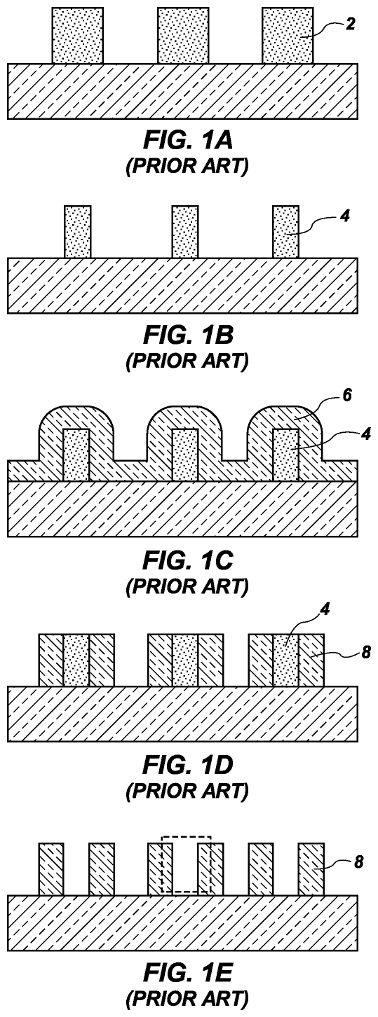

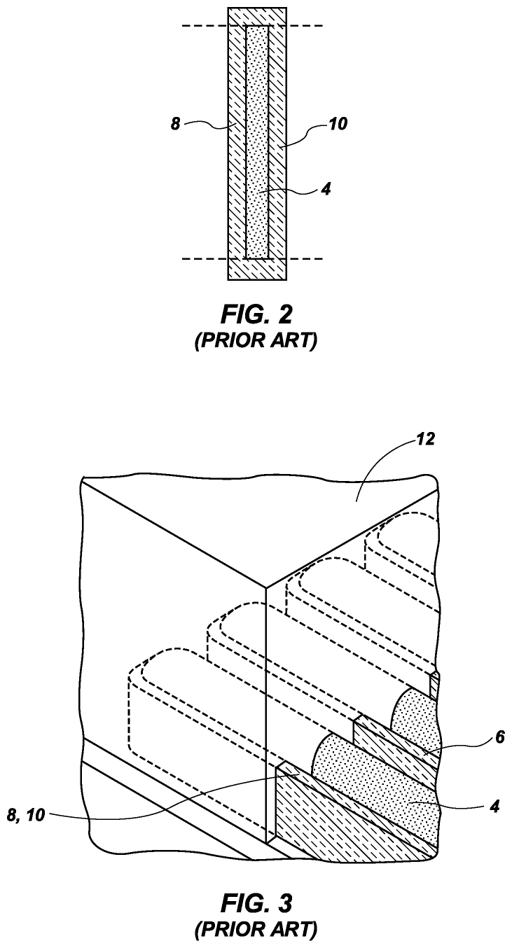

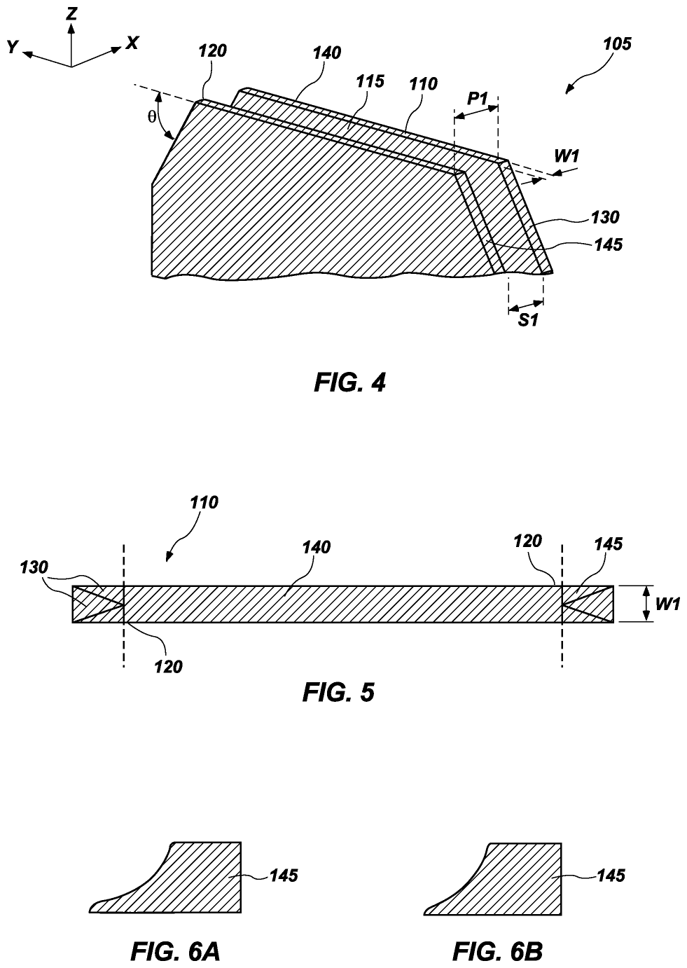

A method of forming sublithographic features 100 is illustrated in FIGS. 4-12. As shown in FIG. 4, a mandrel 105 including a pattern of lines 110 and spaces 115 is formed. The spaces 115 are delimited by the material of the lines 110. Dimensions (e.g., sizes) and configurations (e.g., shapes) of the lines 110 and spaces 115 of the pattern are selected to form the sublithographic features (less than about 100 nm or less than about 50 nm) at the desired CD on a base material (e.g., substrate) of a semiconductor device. The lines 110 may be equally spaced from one another or may be separated from one another by variable distances. The lines 110 include the sloped profile at opposing ends 120, as shown in FIGS. 4 and 5. The sloped profile is due to sloped surfaces 130 (e.g., sloped walls) at the ends 120 of the lines 110. The ends 120 of the lines 110 are sloped (e.g., not horizontal) in contrast with the substantially horizontal and vertical surfaces of dummy lines in conventional pitch multiplication processes (see, for example, FIG. 1A). The ends 120 of the lines 110 include the sloped surfaces 130 that extend from a top horizontal surface of the lines 110 to a bottom horizontal surface of the lines 110 in the y direction. The ends 120 of the lines 110 may also include the sloped surfaces 130 in the z direction from a top horizontal surface of the lines 110 to a bottom horizontal surface of the lines 110, as shown in FIG. 5. The sloped surfaces 130 of the ends 120 of the lines 110 may, therefore, be sloped in one or more of the horizontal and vertical directions. The sloped surfaces 130 of the lines 110 may exhibit a substantially linear slope, as shown in FIG. 4 or 5, or a non-linear slope, as shown in FIGS. 6A and 6B. An angle θ measured between a line (the dashed line in FIG. 4) extending from the horizontal top surface of the lines 110 and the sloped surface 130 may range from about 10 degrees to about 85 degrees, such as from about 45 degrees to about 85 degrees or from about 70 degrees to about 85 degrees.

As shown in FIG. 4, the pattern of lines 110 and spaces 115 is present at a top portion of the mandrel 105. The lines 110 are formed at a pitch P1, with the pitch P1 equal to the sum of a width W1 of the lines 110 and a spacing S1 between adjacent lines 110. The pitch P1 may range from about 40 nm to about 400 nm, such as from about 100 nm to about 200 nm or from about 40 nm to about 100 nm. The width W1 of the lines 110 may be at or near the limit of a photolithography technique used to form the lines 110. By way of example only, the width W1 of the lines 110 may be less than about 200 nm, less than about 150 nm, less than about 140 nm, less than about 130 nm, less than about 120 nm, less than about 110 nm, less than about 100 nm, less than about 90 nm, less than about 80 nm, less than about 70 nm, less than about 60 nm, or less than about 50 nm. The width W1 of the lines 110 may be from about 20 nm to about 200 nm or from about 20 nm to about 100 nm. The spacing S1 may range from about 20 nm to about 200 nm, such as from about 100 nm to about 180 nm, from about 100 nm to about 170 nm, from about 100 nm to about 160 nm, from about 100 nm to about 150 nm, from about 100 nm to about 140 nm, from about 100 nm to about 130 nm, from about 100 nm to about 120 nm, or from about 100 nm to about 110 nm. Alternatively, the lines 110 may be formed at an initial width greater than W1 (not shown) where the adjacent lines 110 are spaced apart a distance less than S1. A portion of the material is removed (e.g., trimmed) to form the lines 110 having the width W1, which increases the distance separating the lines 110 to the spacing S1. The removal (e.g., trim) process for removing the portion of the lines 110 may be an isotropic etch. In some embodiments, the lines 110 are formed by photolithography at the desired width W1 and spacing S1. In other embodiments, the lines 110 are formed by photolithography at the width greater than W1 and the spacing less than S1 and trimmed (e.g., etched) to the width W1 and spacing S1.

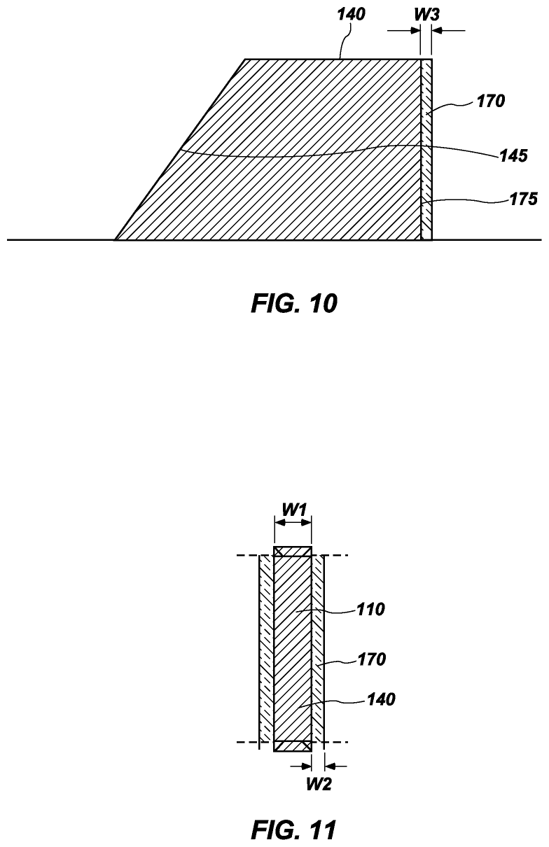

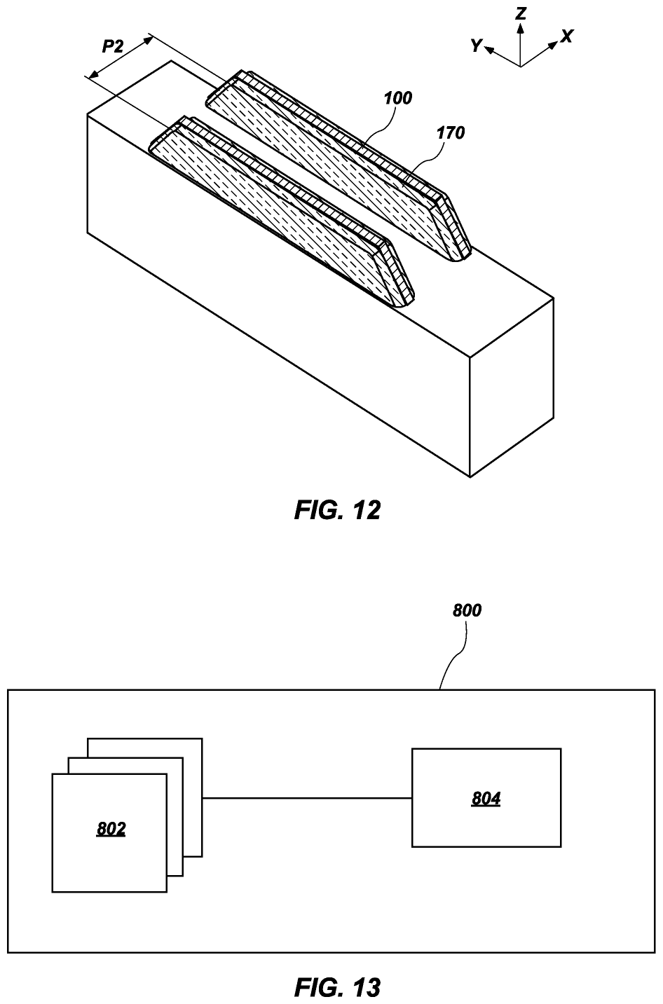

The width W1 of the lines 110 corresponds to spacing between spacers (see FIGS. 10 and 11) subsequently formed, and also to the width of the sublithographic features (see FIG. 12) ultimately to be formed. For simplicity, the mandrel 105 is shown as including two lines 110. However, additional lines 110 may be present to form the desired pattern of lines 110 and spaces 115, depending on the pattern of sublithographic features ultimately to be formed. The lines 110 of the mandrel 105 includes horizontal portions 140 and sloped portions 145 over which a spacer material is subsequently formed. The sloped portions 145 exhibit the sloped profile and are positioned at the opposing ends 120 (e.g., end portions) of the horizontal portions 140 of the lines 110. The lines 110 may be referred to as so-called “dummy” lines since the lines 110 are removed after forming the spacers on the lines 110. As discussed below, the sloped portions 145 of the lines 110 cause the spacer material formed thereover to exhibit a corresponding sloped profile. While not illustrated in FIG. 4, the lines 110 may be positioned over one or more material(s), such as a target material or base material, in which or on which the sublithographic features are to be formed.

The mandrel 105 may be formed from a photoresist material, a hard mask material, or other material that is selectively etchable relative to the spacer material. The photoresist material may, for example, be a positive-tone or a negative-tone photoresist resist and may be a 157 nm, 193 nm, 248 nm, or 365 nm photoresist. The hardmask material may be a silicon oxide, a silicon nitride, an amorphous carbon, other carbon material (e.g., a bottom antireflective coating (BARC), a dielectric antireflective coating (DARC), diamond-like material), or other material. The pattern of lines 110 including the sloped profile may be formed by conventional techniques. By way of example only, the sloped profile at the ends 120 of the lines 110 may be formed by variable exposure lithography, such as grey scale lithography, or by utilizing optical proximity correction (OPC) techniques, such as including outriggers and defocus tuning. Variable exposure lithography and OPC techniques are known in the art and are not described in detail herein. Alternatively, the sloped profile may be formed in a photoresist material and the sloped profiled transferred to the lines 110 by conventional techniques, such as by an isotropic etch process. However, other techniques of forming the sloped profile of the lines 110 may also be used.

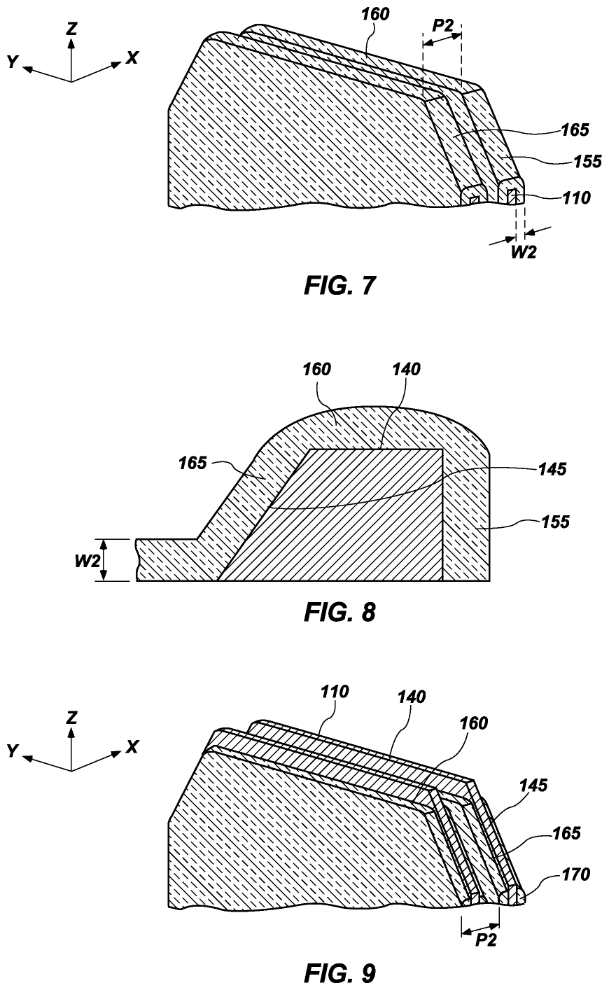

A spacer material 155 may be formed adjacent to (e.g., over) the lines 110 and spaces 115, as shown in FIGS. 7 and 8. The sloped profile of the lines 110 enables the spacer material 155 to be formed at a substantially uniform thickness adjacent to (e.g., over) the lines 110. However, the thickness W2 of the spacer material 155 over the horizontal portions 140 may vary relative to other portions of the spacer material 155. The spacer material 155 is formed substantially completely over exposed surfaces of the lines 110, including over the horizontal portions 140 and the sloped portions 145 of the lines 110 and in the spaces 115 between the lines 110. The spacer material 155 may be conformally formed over the lines 110, such as by ALD or CVD. Therefore, the spacer material 155 includes horizontal portions 160 substantially overlying the horizontal portions 140 of the lines 110 and sloped portions 165 substantially overlying the sloped portions 145 of the lines 110. The spacer material 155 may be an oxide material, a polysilicon material, a silicon nitride material, an amorphous carbon, other carbon material (e.g., a bottom antireflective coating (BARC), a dielectric antireflective coating (DARC), diamond-like material), or other material selectively etchable relative to the material of the lines 110. The oxide material may include, but is not limited to, a silicon oxide (SiOₓ), such as silicon dioxide (SiO₂). A thickness at which the spacer material 155 is formed may be selected depending on a desired width W2 of the spacers 170. By way of example only, the spacer material 155 may be formed at a thickness of from about 20 nm to about 80 nm, such as from about 20 nm to about 60 nm, from about 20 nm to about 40 nm, from about 40 nm to about 80 nm, or from about 40 nm to about 60 nm.

Portions of the spacer material 155 are removed, as shown in FIGS. 9, 10, and 11, to form spacers 170 adjacent to vertical sidewalls 175 of the lines 110. The spacers 170 are formed by a so-called “spacer etch” process in which the spacer material 155 is subjected to an anisotropic removal (e.g., etch) process that substantially removes the spacer material 155 from the horizontal portions 140 of the lines 110 while the spacer material 155 substantially remains on the vertical sidewalls 175 of the lines 110. The anisotropic etch process also substantially removes the spacer material 155 overlying the sloped portions 145 of the lines 110. Therefore, the horizontal portions 160 and the sloped portions 165 of the spacer material 155 are substantially removed to form the spacers 170. The spacer material 155 may be substantially removed from the sloped portions 145 of the lines 110 due to the tapered profile and may also be substantially removed from the horizontal portions 140 of the lines 110. However, the spacer material 155 substantially remains on the vertical sidewalls 175 of the lines 110 and forms a pattern of the spacers 170. A width W3 of the spacer material 155 remaining on the vertical sidewalls 175 may be less than the width W2 at which the spacer material 155 was formed. The anisotropic etch process used to remove the spacer material 155 may use a conventional etch chemistry and conventional etch conditions. The appropriate etch chemistry for removing the spacer material 155 may be selected by a person of ordinary skill in the art depending on the material used as the spacer material 155.

While FIG. 9 illustrates a top surface of the spacer material 155 as being recessed relative to a top surface of the lines 110, the top surface of the spacer material 155 may be substantially coplanar with the top surface of the lines 110, as shown in FIG. 10, by adjusting the etch conditions, such as the etch time, etch temperature, etc. Without being bound by any theory, it is believed that the horizontal portions 160 and the sloped portions 165 of the spacer material 155 are selectively removed due to increased exposure to active species (e.g., ions) of the etch process. The horizontal portions 160 and the sloped portions 165 of the spacer material 155 are subjected to increased ion bombardment from the etch chemistry compared to the vertical portions of the spacer material 155. The spacer material 155 may, therefore, be removed from over the horizontal portions 140 and the sloped portions 145 of the lines 110 at a faster rate compared to the rate of removal from the vertical sidewalls 175. Therefore, by appropriately selecting the etch time, the removal of the spacer material 155 may be controlled such that the spacer material 155 is removed from the horizontal portions 140 and the sloped portions 145 of the lines 110.

As shown in FIG. 11, the spacers 170 are formed as two discrete (e.g., not connected) lines adjacent to the vertical sidewalls 175 of the lines 110. In comparison, spacers 8 formed by a conventional pitch multiplication process include the loops 10 (see FIGS. 2 and 3) of the spacer material 6 surrounding sidewalls and ends of the photoresist features 4. The spacers 170 have a pitch P2 that is equal to about one-half of the pitch P1 of the lines 110. Therefore, the pitch P2 of the spacers 170 has been doubled relative to the pitch P1 of the lines 110. Since the spacer material 155 is removed from the ends 120 of the lines 110, no loops are present following the formation of the spacers 170 according to embodiments of the disclosure. Since no loops are formed, no chop masks or chop mask process acts are necessary to open the loops. Therefore, the formation of the spacers 170 according to embodiments of the disclosure may be conducted without utilizing chop masks or chop mask process acts.

Removal of the lines 110 forms openings (not shown) between the spacers 170. A material is formed in the openings to form sublithographic features 100 having the reduced pitch, as shown in FIG. 12. The sublithographic features 100 may be equally spaced from one another or may be separated from one another by variable distances. Depending on the sublithographic features 100 to be formed, a conductive material or other desired material may be formed in the openings to produce the sublithographic features 100. The spacers 170 are subsequently removed, such as by a removal (e.g., etch) process, forming the sublithographic features 100 at the pitch P2, which is reduced (e.g., halved) relative to the pitch P1 of the lines 110. Alternatively, the pattern of the spacers 170 is transferred to one or more underlying materials to form the sublithographic features 100 at the pitch P2 in the target material. The spacers 170 are subsequently removed, such as by a removal (e.g., etch) process. The additional acts to form the sublithographic features 100 may be conducted by conventional techniques, which are not described in detail herein. The sublithographic features 100 are, therefore, formed without utilizing chop masks or conducting chop mask process acts.

The conductive material may, for example, be a metal (e.g., tungsten, titanium, molybdenum, niobium, vanadium, hafnium, tantalum, chromium, zirconium, iron, ruthenium, osmium, cobalt, rhodium, iridium, nickel, palladium, platinum, copper, silver, gold, aluminum), a metal alloy (e.g., a cobalt-based alloy, an iron-based alloy, a nickel-based alloy, an iron- and nickel-based alloy, a cobalt- and nickel-based alloy, an iron- and cobalt-based alloy, a cobalt- and nickel- and iron-based alloy, an aluminum-based alloy, a copper-based alloy, a magnesium-based alloy, a titanium-based alloy, a steel, a low-carbon steel, a stainless steel), a conductive metal-containing material (e.g., a conductive metal nitride, a conductive metal silicide, a conductive metal carbide, a conductive metal oxide), polysilicon, a conductively-doped semiconductor material (e.g., conductively-doped silicon, conductively-doped germanium, conductively-doped silicon germanium), other conductive material, or a combination thereof. The conductive sublithographic features 100 may include, but are not limited to, bit lines, word lines, interconnect lines, landing pads, or contacts.

Subsequent process acts are conducted to connect the conductive sublithographic features 100 (e.g., bit lines, word lines) to other components of the semiconductor device. The subsequent process acts may be conducted by conventional techniques, which are not described in detail herein.

While FIG. 12 illustrates the pitch P2 as being doubled, one or more additional pitch multiplication processes may be conducted to further reduce the pitch. For example, after removing the lines 110 between the spacers 170, an additional pitch multiplication process may be conducted to reduce the pitch of the pitch multiplied features (e.g., the sublithographic features 100) to one-quarter of the pitch P1. The pitch may be further reduced by forming additional spacer material on the vertical sidewalls of the spacers 170, removing the spacers 170 to form openings between the additional spacer material, and forming another conductive material or other desired material in the resulting openings. The additional spacer material may be formed as described above so that the additional spacer material includes sloped portions 165. The conductive material or other desired material may be formed in the openings to produce the sublithographic features at the desired pitch that is smaller than the pitch P1 and the pitch P2.

Accordingly, a method of forming sublithographic features is disclosed. The method comprises forming a pattern of lines at a first pitch, the lines comprising horizontal portions and sloped portions. A spacer material is formed adjacent to the lines. Portions of the spacer material are removed to form spacers on the lines, the spacers comprising a second pitch. The lines are removed.

Accordingly, another method of forming sublithographic features is disclosed. The method comprises forming a spacer material adjacent to a pattern of lines, the spacer material comprising horizontal portions and sloped portions. Portions of the spacer material are removed to form spacers on the lines without utilizing a chop mask. The lines are removed to form openings between the spacers. A material is formed in the openings.

Accordingly, another method of forming sublithographic features is disclosed. The method comprises forming lines comprising horizontal portions and sloped portions at a first pitch. A spacer material comprising horizontal portions and sloped portions is conformally formed adjacent to the lines. The horizontal portions and sloped portions of the spacer material are substantially removed to form spacers on sidewalls of the lines, the spacers comprising a second pitch smaller than the first pitch. The lines are removed to form openings between the spacers and a conductive material is formed in the openings.

While embodiments of forming the sublithographic features 100 described and illustrated in FIGS. 4-12 utilize a pitch multiplication process, the sloped profile of the spacer material 155 may be used in other processes where spacers 170 are to be formed around lines 110 of a photoresist material or hardmask material and where loops of the spacer material 155 are not desired. The embodiments of forming the sublithographic features 100 may be used to form sublithographic features whenever a spacer formation process is utilized. The embodiments of forming the sublithographic features 100 may also be used in other processes where a chop mask is utilized to open loops of a spacer material.

Semiconductor devices including the sublithographic features 100 may be formed by conducting additional process acts depending on the sublithographic features 100 to be present in the semiconductor device. By way of example only, the semiconductor device may be a memory device that includes the sublithographic features 100 in a memory array of memory cells. A semiconductor device, such as a memory device 800, is also disclosed, as shown schematically in FIG. 13. The memory device 800 includes a memory array 802 of memory cells including the sublithographic features 100 and a control logic component 804. The control logic component 804 may be configured to operatively interact with the memory array 802 so as to read, write, or re-fresh any or all memory cells within the memory array 802. The methods according to embodiments of the disclosure may be used to form sublithographic features of semiconductor devices including, but not limited to, DRAM devices, FinFET devices, crosspoint devices, NAND devices, or other memory devices in which a pitch multiplication process or spacer etch process is used. The additional process acts to form the semiconductor device may be conducted by conventional techniques, which are not described in detail herein.

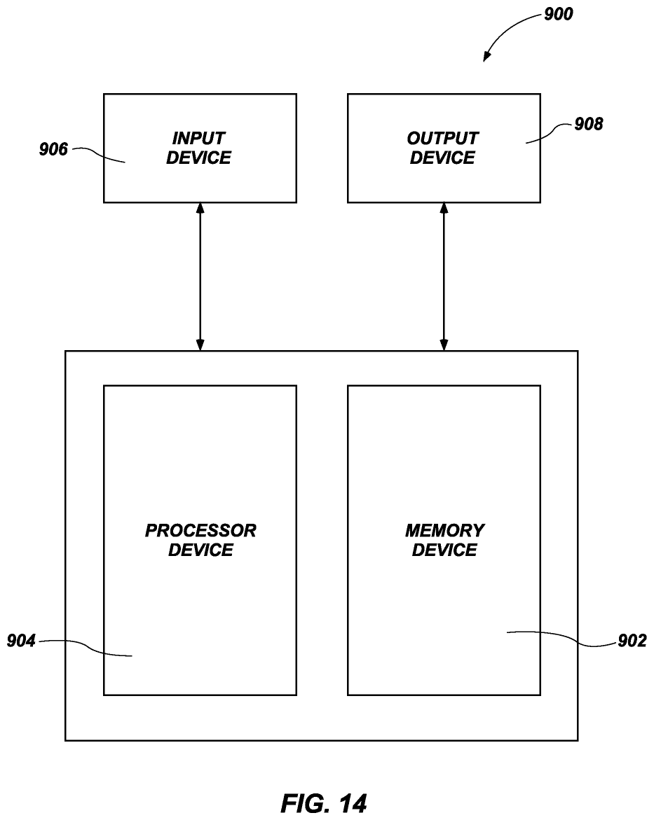

A system 900 is also disclosed, as shown in FIG. 14, and includes the sublithographic features 100. FIG. 14 is a simplified block diagram of the system 900 implemented according to one or more embodiments described herein. The system 900 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The system 900 includes at least one memory device 902, which includes memory cells including the sublithographic features 100 as previously described. The system 900 may further include at least one processor device 904 (often referred to as a “processor”). The processor device 904 may, optionally, include sublithographic features 100 as previously described. The system 900 may further include one or more input devices 906 for inputting information into the electronic system 900 by a user, such as, for example, a mouse or other pointing device, a keyboard, a touchpad, a button, or a control panel. The electronic system 900 may further include one or more output devices 908 for outputting information (e.g., visual or audio output) to a user such as, for example, a monitor, a display, a printer, an audio output jack, a speaker, etc. In some embodiments, the input device 906 and the output device 908 may comprise a single touchscreen device that can be used both to input information to the electronic system 900 and to output visual information to a user. The one or more input devices 906 and output devices 908 may communicate electrically with at least one of the memory device 902 and the processor device 904.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. A method of forming sublithographic features, comprising:
forming a pattern of lines at a first pitch, the lines comprising horizontal portions and sloped portions;
forming a spacer material adjacent to the lines;
removing portions of the spacer material to form spacers on the lines, the spacers comprising a second pitch; and
removing the lines.

2. The method of claim 1, wherein forming a pattern of lines comprises forming the sloped portions at opposing ends of the horizontal portions of the lines.

3. The method of claim 1, wherein forming a pattern of lines at a first pitch comprises forming the lines at a first pitch of from about 40 nm to about 100 nm.

4. The method of claim 1, wherein forming a spacer material adjacent to the lines comprises conformally forming the spacer material adjacent to the lines.

5. The method of claim 1, wherein forming a spacer material adjacent to the lines comprises forming horizontal portions and sloped portions of the spacer material.

6. The method of claim 5, wherein forming horizontal portions and sloped portions of the spacer material comprises forming the sloped portions comprising a linear slope.

7. The method of claim 5, wherein forming horizontal portions and sloped portions of the spacer material comprises forming the sloped portions comprising a non-linear slope.

8. The method of claim 1, wherein removing portions of the spacer material to form spacers on the lines comprises removing portions of the spacer material overlying the horizontal portions of the lines and the sloped portions of the lines.

9. The method of claim 1, wherein removing portions of the spacer material to form spacers on the lines comprises forming the spacers on sidewalls of the lines.

10. The method of claim 1, further comprising, after removing the lines, forming a conductive material between the spacers to form conductive features at the second pitch.

11. The method of claim 10, wherein forming conductive features at the second pitch comprises forming the conductive features at a pitch of less than about 100 nm.

12. A method of forming sublithographic features, comprising:
forming a spacer material adjacent to a pattern of lines, the spacer material comprising horizontal portions and sloped portions;
removing portions of the spacer material to form spacers on the lines without utilizing a chop mask;
removing the lines to form openings between the spacers; and
forming a material in the openings.

13. The method of claim 12, wherein forming a spacer material adjacent to a pattern of lines comprises forming the spacer material by atomic layer deposition.

14. The method of claim 12, wherein removing portions of the spacer material to form spacers on the lines comprises substantially removing the horizontal portions and the sloped portions of the spacer material without substantially removing the spacer material from sidewalls of the lines.

15. The method of claim 12, wherein removing portions of the spacer material to form spacers on the lines comprises substantially removing the spacer material from sloped surfaces of the lines.

16. The method of claim 12, wherein removing portions of the spacer material to form spacers on the lines comprises forming discrete, electrically isolated spacers on sidewalls of the lines.

17. The method of claim 16, further comprising forming an additional spacer material on the sidewalls of the spacers.

18. The method of claim 12, wherein forming a material in the openings comprises forming a conductive material in the openings.

19. A method of forming sublithographic features, comprising:
forming lines comprising horizontal portions and sloped portions at a first pitch;
conformally forming a spacer material comprising horizontal portions and sloped portions adjacent to the lines;
substantially removing the horizontal portions and the sloped portions of the spacer material to form spacers on sidewalls of the lines, the spacers comprising a second pitch smaller than the first pitch;
removing the lines to form openings between the spacers; and
forming a conductive material in the openings.

20. The method of claim 19, wherein substantially removing the horizontal portions and the sloped portions of the spacer material to form spacers on sidewalls of the lines comprises substantially removing the horizontal portions and the sloped portions of the spacer material without substantially removing the spacer material on the sidewalls of the lines.

21. The method of claim 19, wherein forming a conductive material in the openings comprises forming conductive features at a critical dimension of less than about 50 nm.
